(19) United States
(12) Patent Application Publication
(10) Pub. No.: US 2026/0082666 A1
(43) Pub. Date: Mar. 19, 2026

(54) VERTICAL DEVICE AND SEMICONDUCTOR MODULE

(71) Applicant: FUJI ELECTRIC CO., LTD., Kanagawa (JP)

(72) Inventor: Shinji SANO, Matsumoto-city (JP)

(21) Appl. No.: 19/399,386

(22) Filed: Nov. 24, 2025

Related U.S. Application Data
(63) Continuation of application No. PCT/JP2024/037264, filed on Oct. 18, 2024.

(30) Foreign Application Priority Data
Dec. 21, 2023 (JP) 2023-216303

(51) Int. Cl. H10D 64/62; H01L 23/00; H01L 23/498

(52) U.S. Cl. CPC H10D 64/62; H10W 70/658; H10W 90/734

(57) ABSTRACT

There is provided a vertical device including: a semiconductor substrate which has an upper surface and a lower surface; and a lower electrode which is provided on the entire lower surface of the semiconductor substrate, in which the lower electrode contains copper. The lower electrode may have a lowermost layer which is exposed at a surface that is farthest away from the lower surface of the semiconductor substrate, the lowermost layer may contain copper, a ratio of copper in the lowermost layer may be 50 wt% or more and 90 wt% or less, and a thickness of the lowermost layer may be 0.2 μm or more and 0.8 μm or less.

The contents of the following patent application(s) are incorporated herein by reference: NO. 2023-216303 filed in JP on December 21, 2023 NO. PCT/JP2024/037264 filed in WO on October 18, 2024.

### BACKGROUND

### 1. TECHNICAL FIELD

The present invention relates to a vertical device and a semiconductor module.

### 2. RELATED ART

In the related art, a configuration is known to provide an Au-Cu alloy layer at a bonded portion when an electronic component is bonded to a substrate by using a heat-bonding material (refer to Patent Document 1). In addition, a stacked film of Ti/Ni/Au is used as a back surface electrode of a power device (refer to Non-Patent Document 1).

### RELATED ART DOCUMENTS

### Patent Documents

Patent Document 1: Japanese Patent Application Publication No. 2015-90900

### Non-Patent Document

Non-Patent Document 1: Kimiharu KAYUKAWA and the other two, "Microstructures and Adhesion Properties at the Interface between Lead-free Solder and Backside-electrodes of Power Devices", Denso Technical Review, 2006, Vol. 11, No. 2, pp. 108 - 114

### BRIEF DESCRIPTION OF THE DRAWINGS

FIG. 1 is a diagram showing a vertical device 100 in an embodiment of the present invention.

FIG. 2 is a diagram showing a vertical device 200 in a comparative example.

FIG. 3 is a diagram showing a semiconductor module 300 in an embodiment of the present invention.

FIG. 4 is a diagram showing a semiconductor module 400 in a comparative example.

FIG. 5 is a diagram showing a concentration distribution of a cross-section A-A' of the semiconductor module 300 in FIG. 3.

FIG. 6 is a diagram showing a vertical device 500 in another embodiment.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention. In the present specification, the same parts in each figure are denoted by the same signs and numerals, and the descriptions thereof may be omitted. In addition, for convenience of description, some configurations may not be illustrated.

In the present specification, one side in a direction parallel to a depth direction of a semiconductor substrate is referred to as an "upper" side and another side is referred to as a "lower" side. One surface of two principal surfaces of a substrate, a layer, or another member is referred to as an upper surface, and another surface is referred to as a lower surface. "Upper" and "lower" directions are not limited to a direction of gravity, or a direction in implementation of a semiconductor device.

In the present specification, technical matters may be described using an orthogonal coordinate system of an X axis, a Y axis, and a Z axis. The orthogonal coordinate system merely specifies relative positions of components, and does not limit a specific direction. For example, a Z axis direction is not limited to indicating a height direction with respect to the ground. It should be noted that a +Z axis direction and a -Z axis direction are directions opposite to each other. When the Z axis direction is described without describing the signs, it means that the direction is parallel to a +Z axis and a -Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including an X axis direction and a Y axis direction.

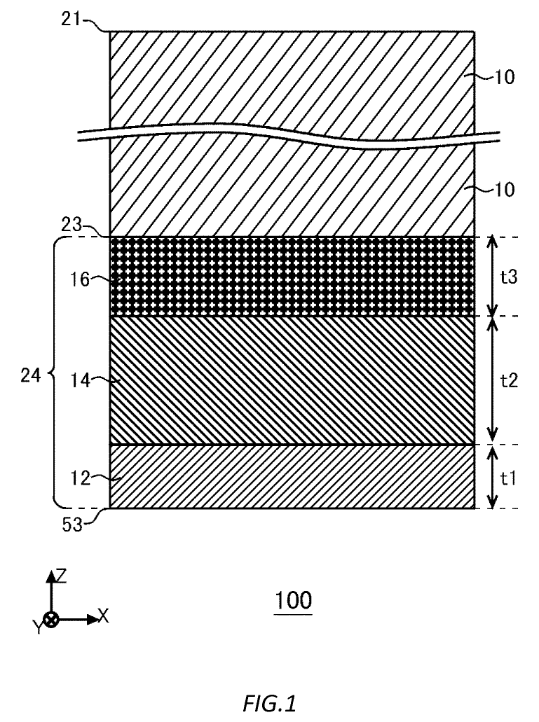

FIG. 1 is a diagram showing a vertical device 100 in an embodiment of the present invention. The vertical device 100 includes a semiconductor substrate 10 and a lower electrode 24. The semiconductor substrate 10 has an upper surface 21 and a lower surface 23. The upper surface 21 and the lower surface 23 are two principal surfaces of the semiconductor substrate 10. The vertical device refers to a semiconductor device in which a main current flows between the upper surface and the lower surface. The vertical device 100 may be a semiconductor device such as a transistor, and is a vertical MOSFET or a vertical IGBT, as an example. For example, the main current is a drain current in a MOSFET or a collector current in an IGBT.

In the semiconductor substrate 10, an element structure of a transistor or the like is formed. For example, on an upper surface 21 side of the semiconductor substrate 10, a MOS gate structure is formed; and above the upper surface 21 of the semiconductor substrate 10, a gate pad and a gate runner for applying a gate voltage to a MOS gate are formed. Further, above the upper surface 21 of the semiconductor substrate 10, a source electrode in the MOSFET or an emitter electrode in the IGBT may be formed. Note that in FIG. 1, structures of the semiconductor substrate 10, and the upper surface 21 of the semiconductor substrate 10 are omitted. As an example, the semiconductor substrate 10 is a silicon substrate or a silicon carbide substrate.

The lower electrode 24 is provided in contact with the lower surface 23 of the semiconductor substrate 10. The lower electrode 24 may be provided on the entire surface of the lower surface 23 of the semiconductor substrate 10. The lower electrode 24 corresponds to the drain electrode in the MOSFET or the collector electrode in the IGBT.

Here, the vertical device 100 refers to a state of a chip before being mounted on a module. That is, the vertical device 100 is soldered to a mounting substrate to be connected to an external power supply or the like via a lead frame or the like, and is used, for example, as a semiconductor device for power conversion; however, the vertical device 100 shown in FIG. 1 refers to a state before being soldered to the mounting substrate. For reasons described below, the lower electrode 24 of the vertical device 100 contains copper.

The lower electrode 24 may have a plurality of layers. The lower electrode 24 in the present example has a lowermost layer 12, an intermediate layer 14, and an upper layer 16. Note that the number of layers included in the lower electrode 24 is not limited to this. The lower electrode 24 may have two layers or may have four or more layers.

The lowermost layer 12 is exposed at a surface 53 which is farthest away from the lower surface 23 of the semiconductor substrate 10, in the lower electrode 24. More specifically, the lowermost layer 12 is a layer formed at a position that is farthest away from the lower surface 23 of the semiconductor substrate 10, among the layers of the lower electrode 24, in the depth direction (Z axis direction). That is, the lowermost layer 12 is exposed at the surface 53 of the lower electrode 24. For reasons described below, the lowermost layer 12 may contain copper. The lowermost layer 12 in the present example is an alloy which contains copper and gold. The lowermost layer 12 may have copper and gold as main components. In the present specification, the main component refers to a component, of which a weight ratio is 50% or more. In the lowermost layer 12, a sum of the weight ratio of copper and the weight ratio of gold may be 50% or more. In the lowermost layer 12, a sum of the weight ratio of copper and the weight ratio of gold may be 100%. The lowermost layer 12 may be an alloy which contains copper and silver. The lowermost layer 12 may refer to a region which is exposed at the surface 53 of the lower electrode 24, and in which copper is continuously present in the depth direction from the surface 53.

The intermediate layer 14 is positioned between the lowermost layer 12 and the lower surface 23 of the semiconductor substrate 10. In the present example, the intermediate layer 14 is in contact with the lowermost layer 12 and is not in contact with the lower surface 23 of the semiconductor substrate 10. The intermediate layer 14 may contain nickel and may have nickel as a main component. In the present example, in the intermediate layer 14, the weight ratio of nickel is 100%. Nickel in the intermediate layer 14 forms an alloy layer with solder when the vertical device 100 is soldered to the mounting substrate.

The upper layer 16 is positioned between the intermediate layer 14 and the lower surface 23 of the semiconductor substrate 10. The upper layer 16 in the present example is in contact with the intermediate layer 14 and the lower surface 23 of the semiconductor substrate. The upper layer 16 may contain titanium and may have titanium as a main component. In the upper layer 16 in the present example, the weight ratio of titanium is 100%. By providing the upper layer 16 which contains titanium, it is possible to bring the lower electrode 24 into ohmic contact with the semiconductor substrate 10. Note that the lower electrode 24 may further have an uppermost layer which contains aluminum or the like between the upper layer 16 and the lower surface 23. Films of the lowermost layer 12, the intermediate layer 14, and the upper layer 16 are formed, for example, by sputtering. In the sputtering of the lowermost layer 12, an alloy of copper and gold may be used as a target, or separate targets of copper and gold may be prepared and discharged simultaneously.

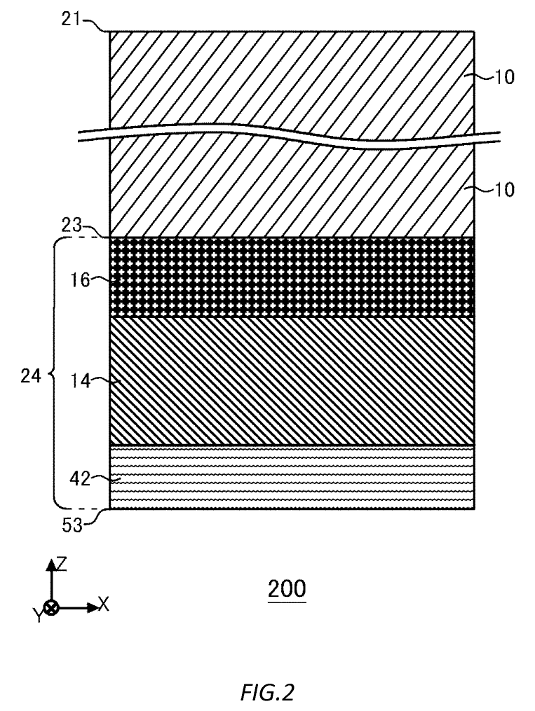

FIG. 2 is a diagram showing a vertical device 200 in a comparative example. In the vertical device 200 in the present example, a configuration of the lower electrode 24 is different from that of the vertical device 100. Other points are similar to those of the vertical device 100, and thus the descriptions are omitted.

The lower electrode 24 in the present example has a gold layer 42 exposed at the surface 53. That is, instead of the lowermost layer 12 in the lower electrode 24 of the vertical device 100, the gold layer 42 is provided. The gold layer 42 is a layer constituted by gold.

In the vertical device 100 of the embodiment, the lowermost layer 12 is set as an alloy, thereby making it possible to decrease an amount of use of expensive gold and to suppress a cost, in comparison with a case where the gold layer 42 of the vertical device 200 is used. In addition, the lowermost layer 12 contains gold, thereby making it possible to maintain solder wettability and corrosion resistance.

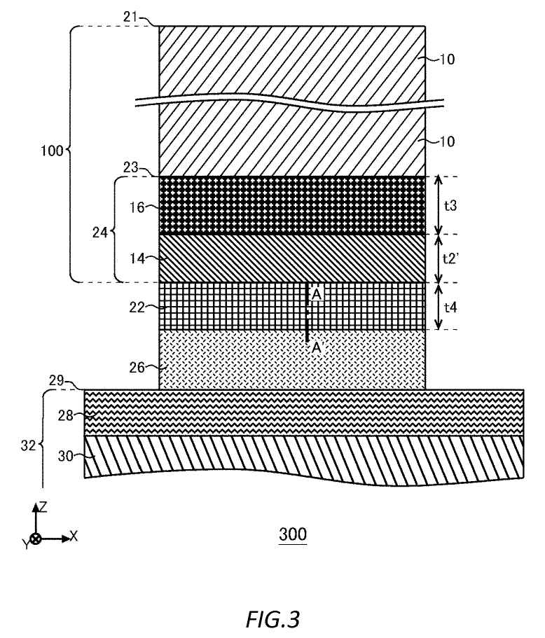

FIG. 3 is a diagram showing a semiconductor module 300 in an embodiment of the present invention. The semiconductor module 300 includes the vertical device 100, and a mounting substrate 32 on which the vertical device 100 is mounted. The vertical device 100 is attached to the mounting substrate 32 by soldering the lower electrode 24. That is, the semiconductor module 300 is in a state after the vertical device 100 is soldered to the mounting substrate 32.

The vertical device 100 in the present example may be similar to the vertical device 100 described in FIG. 1. That is, the vertical device 100 in the present example also includes: the semiconductor substrate 10 having the upper surface 21 and the lower surface 23; and the lower electrode 24 provided on the entire lower surface 23 of the semiconductor substrate 10. Note that the lowermost layer 12 may disappear by soldering as will be described below. The lower electrode 24 in the present example does not have the lowermost layer 12.

The mounting substrate 32 includes a circuit board 30 and a mounting electrode 28. The mounting substrate 32 in the present example may be an insulating circuit board including metal plates on an upper surface and a lower surface of a ceramic plate. In that case, the ceramic plate may correspond to the circuit board 30, and the metal plate corresponds to the mounting electrode 28. The mounting electrode 28 is soldered to the lower electrode 24 of the vertical device 100. The mounting electrode 28 is an electrode which is exposed at a surface 29 of the mounting substrate 32, which is soldered to the vertical device 100.

A bonding layer 22 is formed between the mounting electrode 28 and the lower electrode 24. The bonding layer 22 is an alloy layer which is formed during soldering. The bonding layer 22 in the present example is in contact with the lower electrode 24.

A solder layer 26 is formed between the bonding layer 22 and the mounting substrate 32. The solder layer 26 is a layer of solder which remains without forming the bonding layer 22 during soldering. The solder layer 26 is in contact with the mounting substrate 32.

When the vertical device 100 is soldered to the mounting substrate 32, gold in the lowermost layer 12 diffuses into solder for its high rate of diffusion into solder. Copper in the lowermost layer 12 interdiffuses with tin that is contained in solder to form an alloy. A layer in which the alloy is formed is the bonding layer 22. Therefore, the bonding layer 22 in the present example contains copper and tin. The bonding layer 22 may have copper and tin as main components. In addition, during soldering, nickel in the intermediate layer 14 may interdiffuse with solder to form an alloy layer. In that case, the bonding layer 22 contains nickel. The bonding layer 22 in the present example is an alloy in which a sum of the weight ratio of copper, the weight ratio of tin, and the weight ratio of nickel is 100%. All copper that is contained in the lowermost layer 12 may be contained in the bonding layer 22. The bonding layer 22 may be an alloy which contains at least copper, tin, and nickel; and may have copper, tin, and nickel as main components.

Note that the lowermost layer 12 which contains copper is provided on the surface 53 of the lower electrode 24 and thus forms an alloy with solder more easily than the intermediate layer 14. Further, copper diffuses into solder faster than nickel. Therefore, an atomic composition percentage of copper that is contained in the bonding layer 22 may be greater than an atomic composition percentage of nickel that is contained in the bonding layer 22. The composition ratio of the alloy in the bonding layer 22 may be (Cu, Ni)₆Sn₅ or (Cu, Ni)₃Sn, as an example.

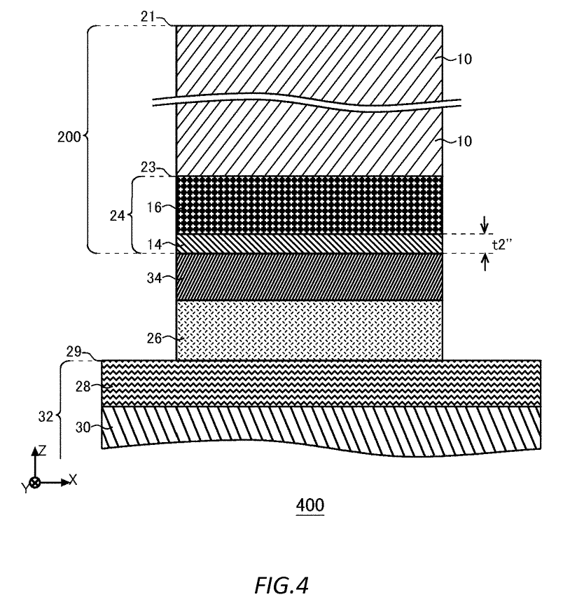

FIG. 4 is a diagram showing a semiconductor module 400 in a comparative example. The semiconductor module 400 is different from the semiconductor module 300 in that the vertical device 200 in the comparative example is soldered to the mounting substrate 32. The configuration of the mounting substrate 32 is similar to that of the semiconductor module 300.

The gold layer 42 of the vertical device 200 diffuses into solder and disappears during soldering. In the semiconductor module 400, a bonding layer 34 is also formed between the mounting substrate 32 and the lower electrode 24. Note that the bonding layer 34 in the present example is an alloy constituted by tin in solder and nickel in the intermediate layer 14. The composition of the bonding layer 34 is Ni₃Sn₄, as an example. In addition, in the semiconductor module 400, the solder layer 26 is formed between the mounting substrate 32 and the bonding layer 34.

Typically, when the vertical device is turned on, the vertical device generates heat. By repeatedly turning on and off, thermal stress is applied to a bonded portion between the vertical device and the mounting substrate, eventually causing a crack to occur at the bonded portion. When the crack occurs, an air layer is formed at the bonded portion, and heat dissipation performance is reduced, which leads to a failure of the vertical device. The number of on/off cycles until the failure occurs is referred to as a dTjP/C withstand value. A case where the dTjP/C withstand value is great means that the bonded portion is strong against the thermal stress. In the semiconductor module in the future, miniaturization and high performance are further required, a power density tends to be increased, and assurance of high-temperature operation is required. Therefore, it is preferable for the dTjP/C withstand value to be great.

The bonding layer 22 which is formed in the semiconductor module 300 and which is an alloy of copper, tin, and nickel has lower rigidity in comparison with the bonding layer 34 which is formed in the semiconductor module 400 and which is an alloy of tin and nickel. Therefore, when the thermal stress is applied to the bonded portion, the bonding layer 22 deforms, thereby suppressing the occurrence of the crack. As a result, the dTjP/C withstand value of the semiconductor module 300 becomes greater than the dTjP/C withstand value of the semiconductor module 400. That is, bonding reliability of the semiconductor module 300 during high-temperature continuous operation is enhanced. In particular, in a case where the semiconductor substrate 10 is a silicon carbide substrate, the rigidity of the silicon carbide substrate is higher than that of the silicon substrate, and thus the operation and the effect described above become more remarkable.

In addition, in a case where the vertical device 200 is soldered, after the gold layer 42 disappears, nickel in the intermediate layer 14 and solder interdiffuse to form the bonding layer 34. On the other hand, in a case where the vertical device 100 is soldered, copper in the lowermost layer 12 preferentially forms an alloy with solder, and thus interdiffusion between nickel in the intermediate layer 14 and solder is less likely to occur than in a case of the vertical device 200. Therefore, a thickness t2' of the intermediate layer 14 in the semiconductor module 300 (refer to FIG. 3) becomes greater than a thickness t2'' of the intermediate layer 14 in the semiconductor module 400 (refer to FIG. 4). That is, it is possible to reduce solder erosion of the intermediate layer 14.

Typically, bondability between titanium that constitutes the upper layer 16, and solder is not good. Therefore, it is preferable that the upper layer 16 does not form an alloy with solder. By reducing the solder erosion of the intermediate layer 14, it is possible to suppress a formation of an alloy between the upper layer 16 and solder even when a soldering condition is a high temperature, and it is possible to enhance bonding reliability of the semiconductor module 300.

The ratio of copper in the lowermost layer 12 of the vertical device 100 (refer to FIG. 1) may be 50 wt% or more. This makes it possible to form the bonding layer 22 which contains copper in the semiconductor module 300. The ratio of copper in the lowermost layer 12 may be 90 wt% or less. By including another element such as gold in the lowermost layer 12, it is possible to maintain solder wettability and corrosion resistance. The ratio of copper in the lowermost layer 12 in the present example is 75 wt%. The ratio of copper in the lowermost layer 12 may be 60 wt% or more, or may be 70 wt% or more, and may be 80 wt% or less.

A thickness t1 of the lowermost layer 12 in the vertical device 100 (refer to FIG. 1) may be 0.2 μm or more. This makes it possible to form the bonding layer 22 which contains copper in the semiconductor module 300. On the other hand, when the thickness t1 of the lowermost layer 12 is too great, warping may occur in the chip during soldering, whereby a void or a shrinkage cavity may occur in the solder layer. Therefore, the thickness t1 of the lowermost layer 12 may be 0.8 μm or less. The thickness t1 of the lowermost layer 12 may be 0.4 μm or more and may be 0.5 μm or less.

The thickness t1 of the lowermost layer 12 may be 0.05 times or more and two times or less of a thickness t2 of the intermediate layer 14 (refer to FIG. 1). By setting the thickness t1 of the lowermost layer 12 and the thickness t2 of the intermediate layer 14 in the ranges described above, it is possible to form the bonding layer 22 which contains copper, and to suppress the formation of an alloy between the upper layer 16 and solder. The thickness t1 of the lowermost layer 12 may be 0.1 times or more of, may be greater than or equal to, or may be two times or more of the thickness t2 of the intermediate layer 14. The thickness t1 of the lowermost layer 12 may be five times or less of, may be three times or less of, or may be smaller than or equal to the thickness t2 of the intermediate layer 14.

The thickness t1 of the lowermost layer 12 may be 0.5 times or more and 20 times or less of a thickness t3 of the upper layer 16 (refer to FIG. 1). The thickness t1 of the lowermost layer 12 may be greater than or equal to or may be two times or more of the thickness t3 of the upper layer 16. The thickness t1 of the lowermost layer 12 may be five times or less or may be three times or less of the thickness t3 of the upper layer 16.

In the semiconductor module 300, an outermost layer of the mounting electrode 28 may not contain copper. As an example, the mounting electrode 28 may have a layer which contains copper; however, the surface 29 of the mounting electrode 28 is covered with NiP plating (from the perspective of corrosion resistance or the like). Alternatively, the mounting electrode 28 may be an aluminum electrode. The outermost layer of the mounting electrode 28 does not contain copper, whereby copper does not diffuse from the mounting substrate 32. In this manner, the bonding layer 22 is formed by copper that is contained in the lowermost layer 12, and thus it becomes easy to control the composition ratio of the bonding layer 22 or the thickness t2'.

In the semiconductor module 300, the solder layer 26 may not contain copper. In other words, solder which does not contain copper may be used to perform soldering. This makes it easy to control the composition ratio of the bonding layer 22 or the thickness t2' as described above. In addition, when an alloy of copper, nickel, and tin is excessively generated in a bulk of the solder layer 26, there is a concern that the bonding reliability may be decreased. Solder does not contain copper, thereby making it possible to selectively form the bonding layer 22 between the lower electrode 24 and the solder layer 26. Further, when copper is excessively added to solder, a melting point of solder sharply rises, and thus a soldering temperature becomes high. Solder does not contain copper, thereby making it possible to lower the soldering temperature. At least a part of the solder layer 26 may not contain copper. The surface of the solder layer 26, which is in contact with the mounting electrode 28 may not contain copper. A part of the solder layer 26, which is closer to a mounting electrode 28 side than the center, in the depth direction, may not contain copper. The ratio of copper that is contained in the solder layer 26 may be 1 wt% or less, may be 0.5 wt% or less, or may be 0.1 wt% or less, and may be 0.01 wt% or more.

An occupying ratio of a weight of copper in the bonding layer 22 to a total weight of the solder layer 26 may be 0.2% or more and 0.8% or less. This makes it possible to form a sufficient amount of the bonding layer 22.

A thickness t4 of the bonding layer 22 (refer to FIG. 3) may be 0.5 μm or more and 10 μm or less. The thickness t4 of the bonding layer 22 may be 1 μm or more or may be 2 μm or more. The thickness t4 of the bonding layer 22 may be 5 μm or less, may be 3 μm or less, may be 2 μm or less, or may be 1 μm or less. In addition, the thickness t4 of the bonding layer 22 may be 0.3 times or more of, may be greater than or equal to, or may be two times or more of the thickness t2' of the intermediate layer 14 in the semiconductor module 300. The thickness t4 of the bonding layer 22 may be 30 times or less, may be five times or less, or may be two times or less of the thickness t2' of the intermediate layer 14.

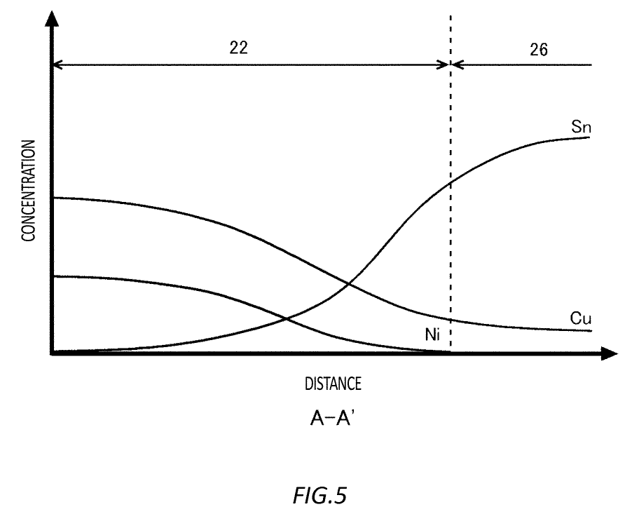

FIG. 5is a diagram showing a concentration distribution of a cross-section A-A' of the semiconductor module 300 in FIG. 3. The cross-section A-A' is a cross section that crosses the bonding layer 22 in the depth direction (Z axis direction) from the interface between the bonding layer 22 and the intermediate layer 14 (lower electrode 24) and reaches an inside of the solder layer 26.

As described above, during soldering, copper in the lowermost layer 12 interdiffuses with solder to form the bonding layer 22. Therefore, in the semiconductor module 300 in the present example, the farther away from the lower electrode 24, the smaller a concentration of copper in the bonding layer 22. The concentration of copper in the bonding layer 22 may be decreased without any increase from the interface with the lower electrode 24 to the interface with the solder layer 26. Hereinafter, the expression of the decrease without any increase may be referred to as a monotonic decrease. All copper that is contained in the bonding layer 22 may be copper that has been contained in the lowermost layer 12.

As described above, during soldering, nickel in the intermediate layer 14 also interdiffuses with solder to form the bonding layer 22. Therefore, in the semiconductor module 300 in the present example, the farther away from the lower electrode 24, the smaller the concentration of nickel in the bonding layer 22. The concentration of nickel in the bonding layer 22 may be decreased monotonically from the interface with the lower electrode 24 to the interface with the solder layer 26. All nickel that is contained in the bonding layer 22 may be nickel that has been contained in the intermediate layer 14. The interface between the bonding layer 22 and the solder layer 26 may be a position of nickel that has diffused the farthest to a solder layer 26 side.

As described above, the lowermost layer 12 which contains copper is provided on the surface 53 of the lower electrode 24 and thus forms an alloy with solder more easily than the intermediate layer 14. Further, copper diffuses into solder faster than nickel. Therefore, the concentration of copper that is contained in the bonding layer 22 may be greater than the concentration of nickel that is contained in the bonding layer 22. For the concentration, an average value of a concentration distribution over an entire region of the bonding layer 22 may be used. In addition, an integrated value of the copper concentration in the entire region of the bonding layer 22 may be greater than an integrated value of the nickel concentration in the entire region of the bonding layer 22.

Tin in solder undergoes the interdiffusion with the lowermost layer 12 and the intermediate layer 14 to form the bonding layer 22. Therefore, in the semiconductor module 300 in the present example, the farther away from the mounting electrode 28 (or the solder layer 26), the smaller the concentration of tin in the bonding layer 22. The interface between the bonding layer 22 and the intermediate layer 14 may be a position of tin that has diffused the farthest to an intermediate layer 14 side.

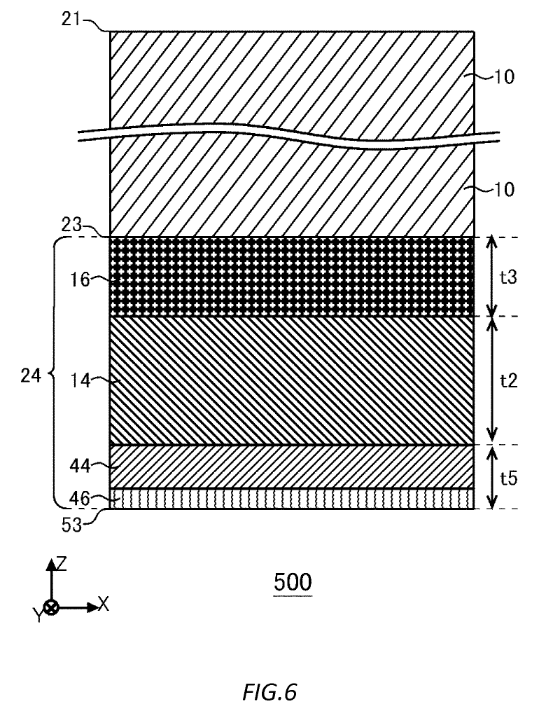

FIG. 6 is a diagram showing a vertical device 500 in another embodiment. The vertical device 500 in the present example includes the semiconductor substrate 10 and the lower electrode 24. The semiconductor substrate 10 is similar to the semiconductor substrate 10 in the vertical device 100.

The lower electrode 24 of the vertical device 500 has a gold-containing layer 46, a copper-containing layer 44, the intermediate layer 14, and the upper layer 16. The intermediate layer 14 and the upper layer 16 of the vertical device 500 may be similar to the intermediate layer 14 and the upper layer 16 of the vertical device 100.

The gold-containing layer 46 in the present example is exposed at the surface 53 which is farthest away from the lower surface 23 of the semiconductor substrate 10, in the lower electrode 24. The gold-containing layer 46 contains gold as a constituent element. The gold-containing layer 46 may have gold as a main component or may be a layer in which the weight ratio of gold is 100%. Note that instead of the gold-containing layer 46, a silver-containing layer which contains silver may be provided. The gold-containing layer 46 in the present example does not contain copper.

The copper-containing layer 44 in the present example is a layer which is in contact with the gold-containing layer 46 and contains copper. The copper-containing layer 44 may have copper as a main component or may be a layer in which the weight ratio of copper is 100%. The copper-containing layer 44 may be a region in which copper is continuously present first from the surface 53 of the lower electrode 24 toward the semiconductor substrate 10. The copper-containing layer 44 in the present example is not exposed at the surface 53 of the lower electrode 24. The copper-containing layer 44 is provided between the gold-containing layer 46 and the intermediate layer 14.

When the vertical device 500 with such a configuration is used, it is also possible to obtain an effect similar to that of the vertical device 100. In addition, when the vertical device 500 is soldered to the mounting substrate 32 to form the semiconductor module, the gold-containing layer 46 diffuses into solder, and the copper-containing layer 44 and the intermediate layer 14 form the bonding layer 22 shown in FIG. 3. Therefore, the semiconductor module can achieve an effect similar to that of the semiconductor module 300. That is, in the semiconductor module, the bonding layer 22 similar to that of the semiconductor module 300 may also be formed, and the concentration distributions of the bonding layer 22 and the solder layer 26 may be similar to the concentration distribution shown in FIG. 5.

A ratio of copper in the copper-containing layer 44 with respect to the gold-containing layer 46 and the copper-containing layer 44 may be 50 wt% or more and 90 wt% or less. The copper-containing layer 44 may be thicker than the gold-containing layer 46. In addition, a total thickness t5 of the gold-containing layer 46 and the copper-containing layer 44 may be replaced with the thickness t1 of the lowermost layer 12 in FIG. 1, and a relationship with the thickness of another layer (for example, t2 or t3) described above may be applied.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

What is claimed is:

1. A vertical device comprising:
a semiconductor substrate which has an upper surface and a lower surface; and
a lower electrode which is provided on the entire lower surface of the semiconductor substrate, wherein
the lower electrode contains copper.

2. The vertical device according to claim 1, wherein
the lower electrode has a lowermost layer which is exposed at a surface that is farthest away from the lower surface of the semiconductor substrate, and
the lowermost layer contains copper.

3. The vertical device according to claim 2, wherein
the lowermost layer is an alloy which contains copper and gold.

4. The vertical device according to claim 2, wherein
a ratio of copper in the lowermost layer is 50 wt% or more.

5. The vertical device according to claim 2, wherein
a ratio of copper in the lowermost layer is 90 wt% or less.

6. The vertical device according to claim 2, wherein
a thickness of the lowermost layer is 0.2 μm or more.

7. The vertical device according to claim 2, wherein
a thickness of the lowermost layer is 0.8 μm or less.

8. The vertical device according to claim 2, wherein
the lower electrode has an intermediate layer between the lowermost layer and the lower surface of the semiconductor substrate, and
the intermediate layer contains nickel.

9. The vertical device according to claim 8, wherein
the lower electrode has an upper layer between the intermediate layer and the lower surface of the semiconductor substrate, and
the upper layer contains titanium.

10. The vertical device according to claim 8, wherein
a thickness of the lowermost layer is 0.05 times or more and two times or less of a thickness of the intermediate layer.

11. The vertical device according to claim 1, wherein
the lower electrode has,
a gold-containing layer which is exposed at a surface that is farthest away from the lower surface of semiconductor substrate, and which contains gold, and
a copper-containing layer which is in contact with the gold-containing layer, and which contains copper.

12. The vertical device according to claim 3, wherein
the lower electrode has an intermediate layer between the lowermost layer and the lower surface of the semiconductor substrate,
the intermediate layer contains nickel, and
the lowermost layer is in contact with the intermediate layer.

13. The vertical device according to claim 12, wherein
a ratio of copper in the lowermost layer is 50 wt% or more.

14. A semiconductor module that includes a vertical device, and a mounting substrate on which the vertical device is mounted, wherein
the vertical device includes,
a semiconductor substrate which has an upper surface and a lower surface, and
a lower electrode which is provided on the entire lower surface of the semiconductor substrate,
the mounting substrate has a mounting electrode which is soldered to the lower electrode of the vertical device,
a bonding layer is formed between the mounting electrode and the lower electrode,
the bonding layer contains copper and tin, and
the farther away from the lower electrode, the smaller a concentration of copper in the bonding layer.

15. The semiconductor module according to claim 14, wherein
an outermost layer of the mounting electrode does not contain copper.

16. The semiconductor module according to claim 14, wherein
a solder layer is formed between the bonding layer and the mounting electrode, and
at least a part of the solder layer does not contain copper.

17. The semiconductor module according to claim 14, wherein
the bonding layer further contains nickel, and
the farther away from the lower electrode, the smaller a concentration of nickel in the bonding layer.

18. The semiconductor module according to claim 17, wherein
an atomic composition percentage of copper that is contained in the bonding layer is greater than an atomic composition percentage of nickel that is contained in the bonding layer.

19. The semiconductor module according to claim 14, wherein
the farther away from the mounting electrode, the smaller a concentration of tin in the bonding layer.

20. The semiconductor module according to claim 14, wherein
a solder layer is formed between the bonding layer and the mounting electrode, and
an occupying ratio of a weight of copper in the bonding layer to a total weight of the solder layer is 0.2% or more and 0.8% or less.
